(19) United States
(12) Patent Application Publication
(10) Pub. No.: US 2012/0018201 A1
(43) Pub. Date: Jan. 26, 2012

(54) CIRCUIT BOARD AND MANUFACTURING METHOD THEREOF, CIRCUIT DEVICE AND MANUFACTURING METHOD THEREOF, AND CONDUCTIVE FOIL PROVIDED WITH INSULATING LAYER

(75) Inventor: Sadamichi TAKAKUSAKI, Ota-shi (JP)

(73) Assignee: ON Semiconductor Trading, Ltd., Hamilton (BM)

(21) Appl. No.: 13/184,078

(22) Filed: Jul. 15, 2011

(30) Foreign Application Priority Data
Jul. 22, 2010 (JP) 2010-164997

(51) Int. Cl. H05K 1/02; H05K 3/00

(52) U.S. Cl. 174/258; 29/829

(57) ABSTRACT

Provided are a circuit board easy to process by laser and a manufacturing method thereof A circuit board of the present invention includes a substrate, an insulating layer covering an upper surface of the substrate, and a conductive pattern of a predetermined shape formed on an upper surface of the insulating layer. The insulating layer is made of a resin material highly filled with a filler made of silica. Further, a colorant made of an inorganic material is added to the resin material. Accordingly, when a laser is radiated onto the insulating layer in order to perform cutting and removing processing, the insulating layer is removed because the laser is absorbed by the colored resin material.

This application claims priority from Japanese Patent Application Number JP 2010-164997 filed on Jul. 22, 2010, the content of which is incorporated herein by reference in its entirety.

### BACKGROUND OF THE INVENTION

1. Field of the Invention

The present invention relates to a circuit board in which a conductive pattern is formed on an upper surface of a substrate covered with an insulating layer and a manufacturing method thereof. The present invention also relates to a circuit device provided with the circuit board having the above-described configuration and a manufacturing method thereof, and to a conductive foil provided with an insulating layer.

2. Description of the Related Art

A circuit such as an inverter circuit which generates a large amount of heat during operation needs to radiate the heat to the outside properly. For example, Japanese Patent Application Publication No. 2010-86993 discloses a circuit device configured to radiate heat generated by a circuit element during operation properly to the outside.

The configuration of the circuit device disclosed in Japanese Patent Application Publication No. 2010-86993 will be described with reference to FIG. 9. In this configuration, a substrate 100 made of a material having excellent heat conductivity such as aluminum is provided with an insulating layer 102 covering an upper surface of the substrate 100 and a conductive pattern 108 of a predetermined shape formed on an upper surface of the insulating layer 102. In addition, a circuit element such as a transistor is electrically connected to a predetermined position on the conductive pattern 108.

The insulating layer 102 is a layer for insulating the conductive pattern 108 from the substrate 100, and is made of a resin material 104 highly filled with a filler 106. Here, epoxy resin is used as the resin material 104, for example, while silica (SiO₂) or alumina (Al₂O₃) is usable as the filler 106. Heat resistance of the insulating layer 102 is reduced by the addition of the filler 106 to the insulating layer 102.

With the above-described configuration, the heat generated from the circuit element connected to the conductive pattern 108 is properly radiated to the outside via the insulating layer 102 and the substrate 100.

However, the circuit board having the above-described configuration has a problem that it is difficult to process the insulating layer 102.

Specific description is provided with reference to FIG. 9. The processing for manufacturing the circuit board includes a step of partially removing the insulating layer 102. This removing step is, for example, a step of exposing part of the upper surface of the substrate 100 or a step of removing part of the substrate 100 together with the insulating layer 102.

A method of mechanical processing such as drilling processing has heretofore been used as the method of removing the insulating layer 102. However, an impact associated with this mechanical processing method leads to a problem that cracks occur in other portions of the insulating layer 102, for example.

Instead of the mechanical processing, a method of radiating a laser 110 has been used as the method of removing the insulating layer 102. The removing method using the laser 110 does not generate an impact unlike the mechanical processing. Therefore, the insulating layer 102 can be removed without occurrence of cracks.

Nevertheless, the radiation of the laser 110 causes another problem when relatively inexpensive silica is used as the filler in the insulating layer 102. Specifically, when light transmissive silica is used as the material of the filler 106, the insulating layer 102 as a whole transmits the laser 110 because the resin material 104 is also made of light transmissive epoxy resin. Accordingly, when the laser 110 is radiated onto the insulating layer 102 from above, the laser 110 is radiated onto the upper surface of the substrate 100 without being attenuated by the insulating layer 102. As a consequence, the radiation of the laser 110 onto the upper surface of the substrate 100 may cause a problem of burning the upper surface of the substrate 100. In addition, the insulating layer 102 is not properly removed even though the laser 110 is radiated.

### SUMMARY OF THE INVENTION

The present invention has been made in view of the aforementioned problems. An object of the present invention is to provide a circuit board easy to process by laser and a manufacturing method thereof. Another object of the present invention is to provide a circuit device which includes the circuit board and a manufacturing method thereof, and to provide a conductive foil including an insulating layer.

A circuit board of the present invention comprises: a substrate; an insulating layer made of a resin material including a filler, the insulating layer covering an upper surface of the substrate; and a conductive pattern formed on an upper surface of the insulating layer, wherein silica is used as the filler included in the resin material, and a colorant is added to the resin material.

A method of manufacturing a circuit board of the present invention comprises the steps of: preparing a substrate by covering an upper surface of the substrate with an insulating layer and forming a conductive pattern of a predetermined shape on a surface of the insulating layer; and removing at least part of the insulating layer by laser processing, wherein the insulating layer includes a resin material to which a colorant is added, and a filler made of silica, and in the removing step, the colored resin material absorbs a laser, and thereby the resin material and the filler included in the insulating layer are removed.

A conductive foil provided with an insulating layer of the present invention serving as a material of a conductive pattern electrically connected to a plurality of circuit elements on an upper surface of a substrate, comprises: a conductive foil made of a conductive material; and an insulating layer made of a resin material including a filler and attached to a principal surface of the conductive foil, wherein silica is used as the filler included in the insulating layer, and a colorant is added to the resin material.

### BRIEF DESCRIPTION OF THE DRAWINGS

FIGS. 1A to 1C are views showing a circuit board and a circuit device according to an embodiment of the present invention, in which FIG. 1A is a perspective view, FIG. 1B is a cross-sectional view, and FIG. 1C is an enlarged cross-sectional view.

FIGS. 2A and 2B are views showing the circuit board and a circuit device according to the embodiment of the present invention, in which FIG. 2A is a cross-sectional view showing a connecting portion formed by laser processing and FIG. 2B is a cross-sectional view showing an end portion of a laser-processed insulating layer.

FIGS. 3A and 3B are views showing the circuit board and the circuit device according to the embodiment of the present invention, in which FIG. 3A is a view showing a resistor portion and FIG. 3B is a cross-sectional view thereof.

FIGS. 4A and 4B are views showing a method of manufacturing the circuit board and the circuit device according to the embodiment of the present invention, in which FIG. 4A is a perspective view showing a conductive foil provided with an insulating layer to be prepared and FIG. 4B is a cross-sectional view thereof.

FIGS. 5A to 5E are cross-sectional views showing the method of manufacturing the circuit board and the circuit device according to the embodiment of the present invention, in which FIGS. 5A to 5E show processes to be carried out to separate a substrate into units.

FIGS. 6A and 6B are views showing the method of manufacturing the circuit board and the circuit device according to the embodiment of the present invention, in which FIGS. 6A and 6B show a process to cut out an insulating layer and a substrate by using a laser.

FIGS. 7A to 7C are views showing the method of manufacturing the circuit board and the circuit device according to the embodiment of the present invention, in which FIGS. 7A to 7C show a process to faun an opening by using the laser.

FIGS. 8A and 8B are views showing the method of manufacturing the circuit board and the circuit device according to the embodiment of the present invention, in which FIGS. 8A and 8B show a process to partially cut out a resistor body by using the laser.

FIG. 9 is a cross-sectional view showing a configuration of a circuit board according to a related art.

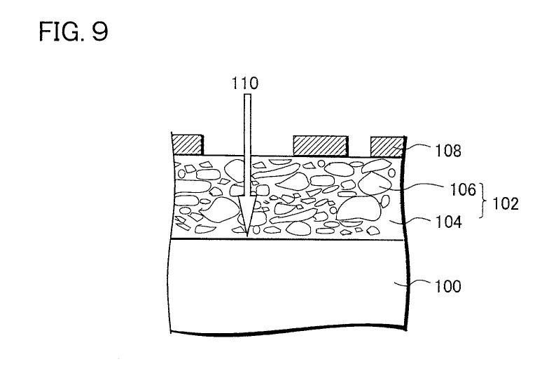

### DESCRIPTION OF THE INVENTION

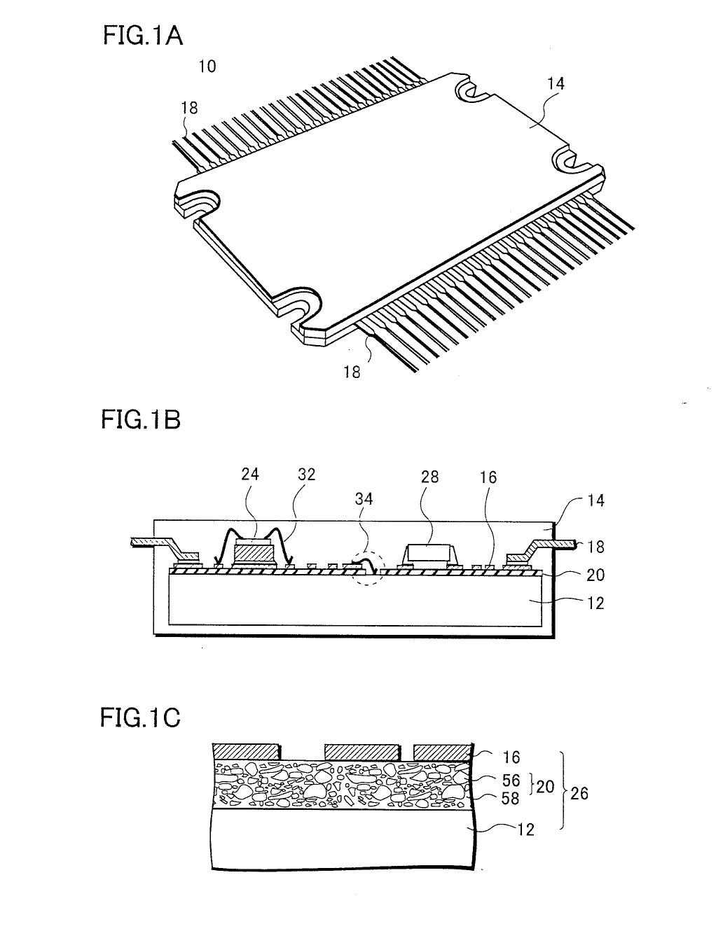

A configuration of a hybrid integrated circuit device 10 employing an embodiment of the present invention will be described with reference to FIGS. 1 A to 1C. FIG. 1A is a perspective view of the hybrid integrated circuit device 10, FIG. 1B is a cross-sectional view thereof, and FIG. 1C is an enlarged cross-sectional view showing a circuit board 26.

The hybrid integrated circuit device 10 includes therein a hybrid integrated circuit formed of a conductive pattern 16 and circuit elements on an upper surface of a substrate 12. Meanwhile, leads 18 that are electrically connected to this circuit are drawn out. Moreover, the hybrid integrated circuit constructed on the upper surface of the substrate 12 as well as the upper surface, side surfaces, and a lower surface of the substrate 12 are integrally covered with sealing resin 14 made of thermosetting resin.

The substrate 12 is a substrate made of metal such as aluminum or copper. Specific dimensions of the substrate 12 are approximately length×width×thickness=61 mm×42 mm×1 mm, for example. Here, a material other than the metal may be used as the material of the substrate 12. For example, a ceramic may be used as the material of the substrate 12. Moreover, when aluminum is used as the material of the substrate 12, the upper surface and the lower surface of the substrate 12 are covered with an oxide film made of alumite, which is formed by anodization.

An insulating layer 20 is made of a resin material highly filled with a filler and is configured to cover the entire upper surface of the substrate 12. Here, the insulating layer 20 is colored in white, black or the like so as to prevent the upper surface of the substrate 12 from being seen through when the insulating layer 20 is viewed from above. Details of this configuration will be described later with reference to FIG. 1C.

The conductive pattern 16 is made of a metal film such as copper having a thickness around 50 μm, and is formed on a surface of the insulating layer 20 so as to realize a predetermined electrical circuit. Moreover, pads made of the conductive pattern 16 are formed on edges where the leads 18 are drawn out. In the drawings, the conductive pattern 16 is formed into a single layer. However, the conductive patterns 16 may be formed into multiple layers with an insulating layer interposed therebetween.

A semiconductor element 24 and a chip element 28 (the circuit elements) are fixed to predetermined positions on the conductive pattern 16 by using a bonding material such as solder. A transistor, an LSI (large scale integrated circuit) chip, a diode or the like is used as the semiconductor element 24. Here, the semiconductor element 24 is connected to the conductive pattern 16 by way of metal thin wires 32. A chip resistor, a chip capacitor or the like is used as the chip element 28. Electrodes on both ends of the chip element 28 are fixed to the conductive pattern 16 by using the bonding material such as solder.

Here, an LED (light-emitting diode) may be used as the element connected to the conductive pattern. With this configuration, the circuit device of this embodiment can be used as an illuminating device.

The leads 18 are fixed to the pads provided at peripheral portions of the substrate 12 and configured to function as external connection terminals to transmit input signals and output signals. As shown in FIG. 1B, numerous leads 18 are provided along two opposed edges of the substrate 12.

The sealing resin 14 is formed by transfer molding which uses the thermosetting resin. In FIG. 1B, the conductive pattern 16, the semiconductor element 24, the chip element 28, and the metal thin wires 32 are sealed with the sealing resin 14. Moreover, the upper surface, the side surfaces, and the lower surface of the substrate 12 are covered with the sealing resin 14.

The configuration of the circuit board 26 will be described further with reference to FIG. 1C. The circuit board 26 includes the substrate 12 made of metal such as aluminum, the insulating layer 20 configured to cover the entire upper surface of the substrate 12, and the conductive pattern 16 formed on the upper surface of the insulating layer 20.

In this embodiment, the insulating layer 20 is made of a colored material in order to facilitate laser processing.

Specifically, a resin material 58 is highly filled with a filler 56 in order to reduce heat resistance of the insulating layer 20. A filling rate of the filler 56 relative to the entire insulating layer 20 is approximately from 60 to 80 percent by volume, for example.

Generally, alumina or silica is used as the material of the filler 56. Moreover, when comparison is made between alumina and silica, alumina has advantages in terms of radiation performance and humidity resistance while silica has an advantage in terms of cost.

Therefore, alumina is used as the filler 56 with priority given to the radiation performance when a power transistor constituting an inverter circuit that generates a very large amount of heat is embedded on the upper surface of the circuit board 26.

Meanwhile, silica is used as the filler 56 in order to reduce the cost when a circuit device generating a small amount of heat or the LED element is embedded on the upper surface of the circuit board 26. In this case, a proportion of silica relative to the entire filler 56 may be equal to or above 50% instead of using only silica as the filler 56.

Cost reduction is achieved by using silica as the material of the filler 56. However, silica is the material that transmits a laser beam. In addition, the resin material 58 made of epoxy resin is also the transparent material that transmits the laser beam. Accordingly, the entire insulating layer 20 is transparent. For this reason, if silica is used as the material of the filler 56, it is difficult to process the insulating layer 20 with the laser as described above.

In this embodiment, a colorant is added to the resin material 58 in order to enable laser processing of the insulating layer 20. Specifically, a colorant made of an inorganic material such as titanium dioxide or carbon is added to the resin material 58 made of epoxy resin. In this way, the resin material 58 is colored in white. Here, the resin material 58 may be colored in color other than white (such as red or black) by changing the ingredient of the colorant to be added thereto.

By coloring the resin material 58 as described above, it is possible to process the insulating layer 20 with the laser. Specifically, when the laser is radiated from above in order to process or to remove the insulating layer 20, the radiated laser beam is absorbed by the colored resin material 58. In this way, the resin material 58 is heated and removed together with the filler 56. Moreover, as the laser is absorbed by the colored resin material 58, the laser is prevented from passing through the insulating layer 20 and reaching the upper surface of the substrate 12. Hence the upper surface of the substrate 12 can be prevented from being damaged by the laser.

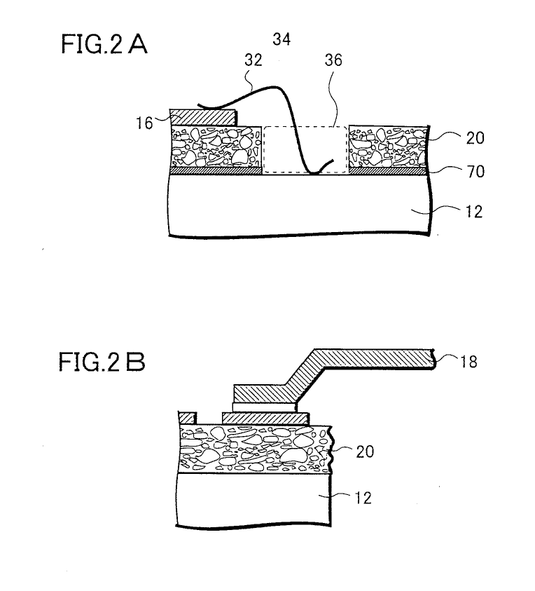

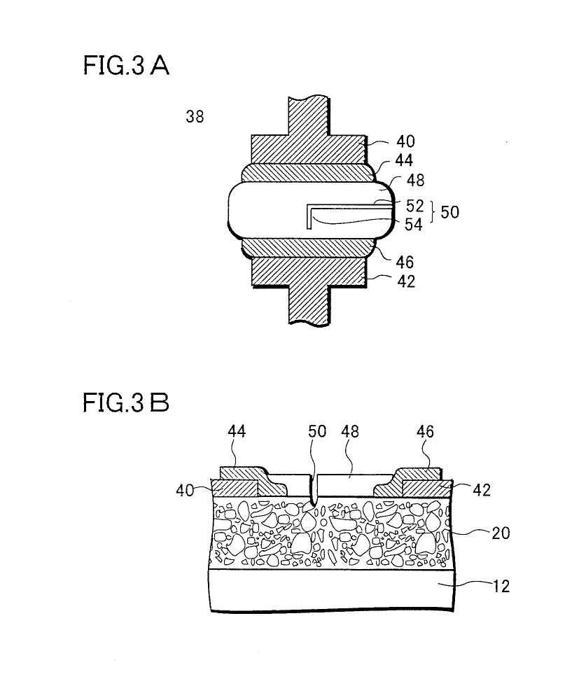

A portion laser-processed in the above-described manner will be described in detail with reference to FIG. 2A to FIG. 3B.

As shown in FIG. 2A, a connecting portion 34 configured to connect the conductive pattern 16 and the substrate 12 together is formed by the above-described laser processing. Specifically, the connecting portion 34 includes an opening 36 provided by partially removing the insulating layer 20, and the metal thin wire 32 configured to connect the conductive pattern 16 and the substrate 12 exposed from the opening 36 together. Meanwhile, when the substrate 12 is made of aluminum, the upper surface of the substrate 12 is covered with an oxide film 70 formed by anodization. However, the oxide film 70 is also removed at the opening 36. Specifically, the insulating layer 20 corresponding to the opening 36 as well as the oxide film 70 therebelow are removed by the laser processing. Therefore, the upper surface of the substrate 12 exposed from the opening 36 is the surface where the metal material such as aluminum is exposed. It is possible to connect the substrate 12 to fixed potential such as power potential or ground potential by connecting the conductive pattern 16 and the substrate 12 together by way of the metal thin wire 32. Accordingly, it is possible to reduce parasitic capacitance occurring between the substrate 12 and the conductive pattern 16.

Reference is now made to FIG. 2B. Here, the insulating layer 20 located on a terminal end of the substrate 12 is cut out by the laser processing. In this case, the large-sized substrate 12 is firstly prepared by covering the upper surface with the insulating layer 20, and then the conductive pattern 16 is formed on the upper surface of the insulating layer 20. Moreover, after the circuit elements as shown in FIG. 1B are electrically connected to the conductive patterns 16, the substrate 12 is cut into a predetermined size in cutting processing. This cutting processing is performed by radiating the laser onto the substrate 12 and the insulating layer 20. The cutting of the substrate 12 and the insulating layer 20 in the laser processing does not cause any impact, which may be caused in the press work, and thereby to prevent such an impact from causing cracks in the insulating layer 20.

Other regions on which the laser processing is performed will be described with reference to FIGS. 3A and 3B. Here, the laser processing is performed on a resistor portion 38 (a printed resistor) which is formed on the upper surface of the substrate. FIG. 3A is a plan view showing the resistor portion 38, and FIG. 3B is a cross-sectional view thereof.

First, two pads 40, 42 are located on the upper surface of the insulating layer 20 so as to face each other. Moreover, conductive pastes 44, 46 are applied to the respective pads 40, 42. Further, a resistor body 48 made of carbon is provided in a region sandwiched by the conductive pastes 44, 46.

As shown in FIG. 3A, a cutout portion 50 is formed by partially cutting out the resistor body 48. The cutout portion 50 includes a first cutout portion 52 extending in an orthogonal direction (a lateral direction) to a direction of current flow (a vertical direction on the sheet surface), and a second cutout portion 54 extending parallel to the direction of current flow. Moreover, as shown in FIG. 3B, the cutout portion 50 is formed so as to penetrate the resistor body 48 and to partially remove the uppermost portion of the insulating layer 20.

These cutout portions are provided to set a resistance value of the resistor portion 38 to a predetermined value. Specifically, the resistance value of the resistor body 48 is set to the predetermined value by adjusting a cross-sectional area of the resistor body 48 through which the current flows. That is, a length of the first cutout portion 52 is determined so as to set the resistance value of the resistor portion 38 to the predetermined value. By providing the first cutout portion 52, the cross-sectional area of the resistor body 48 becomes smaller and the resistance value of the resistor body 48 becomes larger. On the other hand, the second cutout portion 54 provided in the direction of current flow does not affect the resistance value of the resistor body 48. The second cutout portion 54 is provided in order to prevent concentration of the current in an end of the first cutout section.

As shown in FIG. 3B, the cutout portion 50 is formed by the laser processing. Accordingly, when the laser processing is performed so that the cutout portion 50 is provided to penetrate the resistor body 48, the uppermost surface of the insulating layer 20 is also removed slightly. Assuming that the insulating layer 20 is made of a transparent material, the laser beam used for forming the cutout portion 50 passes through the insulating layer 20 and reaches the upper surface of the substrate 12. Hence the laser beam may bum the upper surface of the substrate 12. In this embodiment, since the insulating layer 20 is colored as described above, the laser beam used for forming the cutout portion 50 is absorbed by the insulating layer 20 and is prevented from reaching the upper surface of the substrate 12. As a consequence, the upper surface of the substrate 12 is protected from the laser beam.

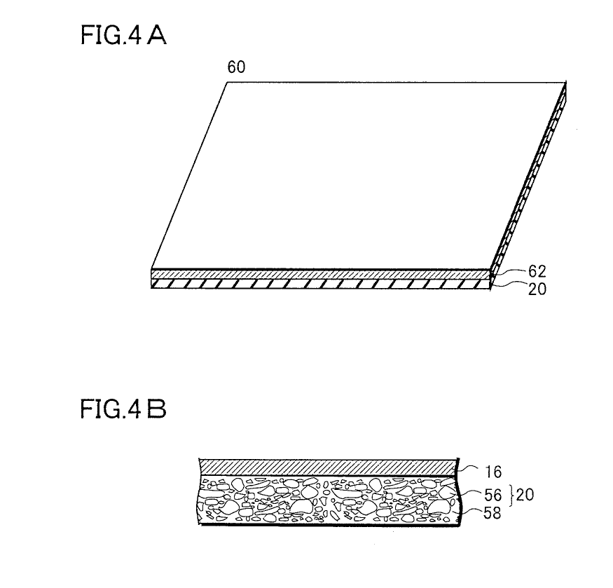

Next, a method of manufacturing the circuit device having the above-described configuration will be explained with reference to FIG. 4A to FIG. 8B.

As shown in FIGS. 4A and 4B, a conductive foil 60 provided with an insulating layer is prepared in the first place. The size in a plan view of the conductive foil 60 provided with the insulating layer is about length×width=1 m×1 m, for example, and serves as the material for several tens to several hundreds of the circuit devices.

The conductive foil 60 provided with the insulating layer includes a conductive foil 62 made of metal such as copper, and the insulating layer 20 attached firmly to a lower surface of the conductive foil 62.

The conductive foil 62 is made of a copper foil formed either by rolling or plating, and a thickness thereof is approximately from 50 μm to 100 μm both inclusive, for example. The conductive foil 62 serves as a material of the conductive pattern of the circuit device.

As described above, the insulating layer 20 is formed in which thermosetting resin such as epoxy resin is highly filled with the filler 56. The thickness of the insulating layer 20 is from 50 μm to 100 μm both inclusive, for example. Here, the insulating layer 20 including the resin material 58 in a semi-cured (B-stage) state is attached to the lower surface of the conductive foil 62. Details of the insulating layer 20 are the same as those described with reference to FIG. 1C.

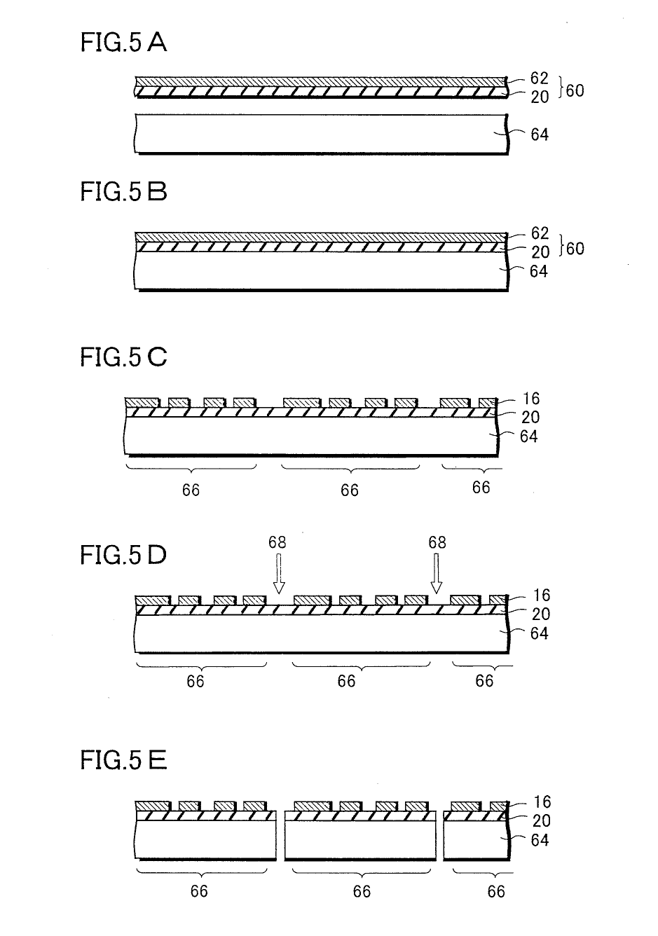

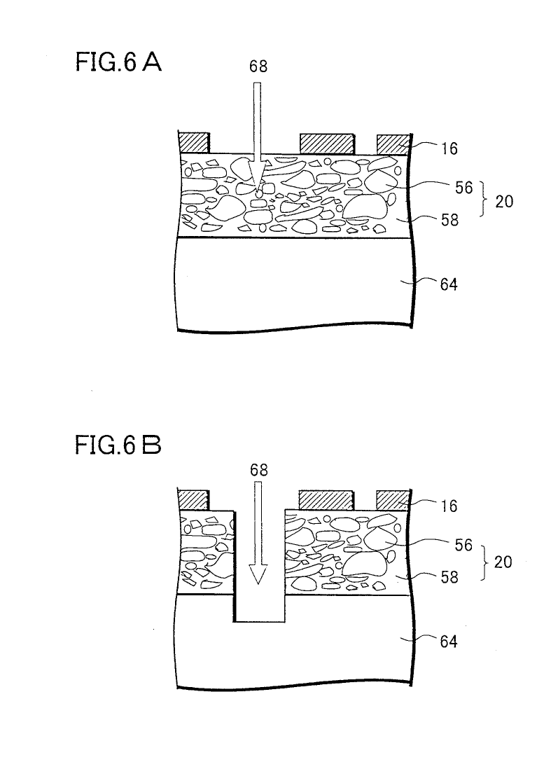

Processes in the course of attaching the conductive foil 60 provided with the insulating layer to a substrate 64 and separating the substrate 64 will be described with reference to FIG. 5A to FIG. 6B. Here, a large-sized substrate 64 is cut out together with the insulating layer 20 by the laser processing.

As shown in FIG. 5A, the conductive foil 60 provided with the insulating layer is firstly attached to an upper surface of the substrate 64. As described above, the resin material included in the insulating layer 20 is in the semi-cured state. Therefore, the insulating layer 20 functions as an adhesive to attach the conductive foil 62 to the substrate 64.

As described above, metal such as copper or aluminum having the thickness around 1 mm is used as the material of the substrate 64. When aluminum is used as the material, the upper surface and the lower surface of the substrate 64 are covered with an oxide film made of alumite.

As shown in FIG. 5B, after the conductive foil 60 provided with the insulating layer is attached to the substrate 64, the resin material included in the insulating layer 20 is cured by heat treatment.

After completing this process, the substrate 64 may be divided into appropriate sizes so as to meet specifications of facilities for subsequent processes such as pattern formation. Here, this dividing method may use the laser processing to be described later.

Next, as shown in FIG. 5C, the conductive patterns 16 in a predetermined shape are foamed by subjecting the conductive foil to selective etching. Here, multiple units 66 each constituting a circuit board are provided on the substrate 64, and the conductive patterns 16 of the same shape are formed on each of the units 66.

As shown in FIG. 5D and FIG. 5E, the substrate 64 is separated for each of the units 66 by radiating a laser. In this process, a laser 68 is radiated from above onto boundary portions of each of the units 66 on the substrate 64. In this way, the insulating layer 20 and the substrate 64 located at the boundary portions of each of the units 66 are removed whereby the units 66 are separated into individual pieces.

Here, a carbon dioxide laser or a YAG (yttrium aluminum garnet) laser is used as the laser 68.

Since the laser processing does not involve mechanical impact unlike punching and so forth, cracks are prevented from occurring in the insulating layer 20 in the course of separating the substrate 64. Meanwhile, if the substrate 64 is separated by dicing, there is a risk of short circuits attributable to chips caused by dicing. However, such a problem is prevented by the laser processing because the laser does not generate any chips.

Details of separation of the substrate 64 by the laser radiation will be described with reference to FIGS. 6A and 6B.

As shown in FIG. 6A, the laser 68 radiated downward firstly reaches the insulating layer 20. As described above, the insulating layer 20 is the mixture of the filler 56 and the resin material 58. Moreover, the filler 56 is made of transparent silica while the resin material 58 is made of colored epoxy resin.

Accordingly, the radiated laser 68 is absorbed by the resin material 58 colored with the colorant. As a result, the resin material 58 and the filler 56 at a portion radiated by the laser 68 are gradually removed from above.

Then, after removal of the insulating layer 20, the substrate 64 made of aluminum is cut out by further radiating the laser 68 as shown in FIG. 6B. Here, if oxide films are formed on both of upper and lower principal surfaces of the substrate 64, these oxide films are also removed by radiating the laser 68.

The substrate 64 is separated into the circuit boards for each of the units by the above-described process. This separation process may be carried out after the circuit elements are electrically connected to the conductive patterns 16. Alternatively, the substrate 64 may be separated before connection of the circuit elements.

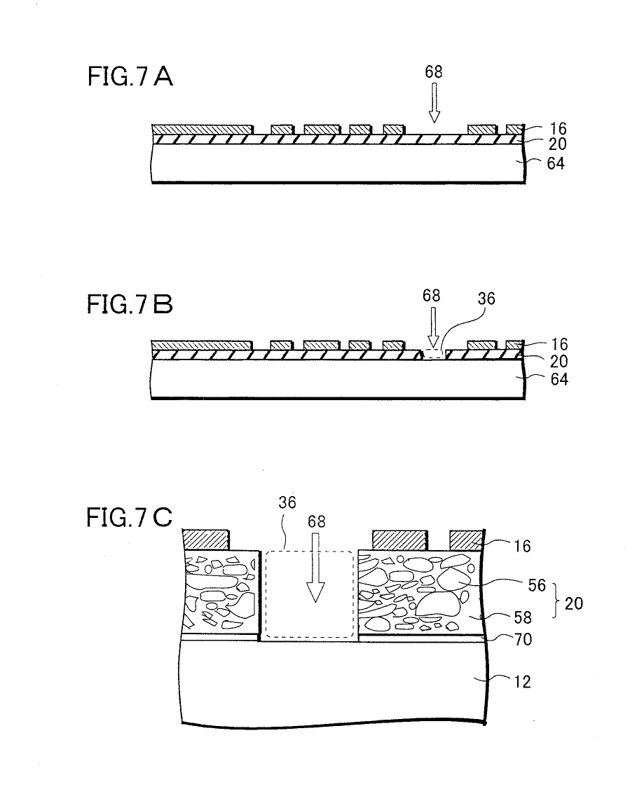

Next, a process to provide the opening 36 by the laser processing will be described with reference to FIGS. 7A to 7C. The opening 36 formed in this process is intended to expose the upper surface of the substrate 12 at the connecting portion 34 as shown in FIG. 2A.

Here, as shown in FIG. 7A and FIG. 7B, the opening 36 is provided by partially removing the insulating layer 20 by radiation of the laser beam 68. Hence the upper surface of the substrate 64 is partially exposed from the opening 36.

Here, as shown in FIG. 7C, the insulating layer 20 is removed by radiation of the laser until the upper surface of the substrate 12 is exposed. Details of the removal of the insulating layer 20 by radiation of the laser are similar to those in the case of FIGS. 6A and 6B.

Further, in this case, the oxide film 70 covering the upper surface of the substrate 12 is removed by radiating the laser 68. In this way, the metal material such as aluminum serving as the material of the substrate 12 is exposed in a flat state to the opening 36. After completion of this process, the conductive pattern 16 and the substrate 64 are connected together by way of the metal thin wire 32 as shown in FIG. 2A.

Drilling processing is generally used as a method of forming the opening 36. However, if the opening 36 is formed by drilling processing, the surface of the substrate 12 exposed to the opening 36 is formed into a rough surface whereby it is difficult to connect the metal thin wire to this portion. For this reason, the exposed portion of the substrate 64 formed into the rough surface is conventionally planarized by pressing, for example. Moreover, there is also a risk that cracks occur in the insulating layer 20 around the opening 36 due to vibrations and the like which are caused by grinding processing with a drill.

On the other hand, according to this embodiment, the upper surface of the substrate 12 is exposed by removing the insulating layer 20 by radiation of the laser. Hence a portion of the surface of the substrate 12 exposed to the opening 36 is basically flat. Accordingly, it is possible to improve connection strength between the surface of the exposed substrate 12 and the metal thin wire to be connected to this portion. Moreover, the processing method by radiation of the laser does not cause mechanical vibrations. Therefore, cracks can be prevented from occurring in the insulating layer 20 around the opening 36.

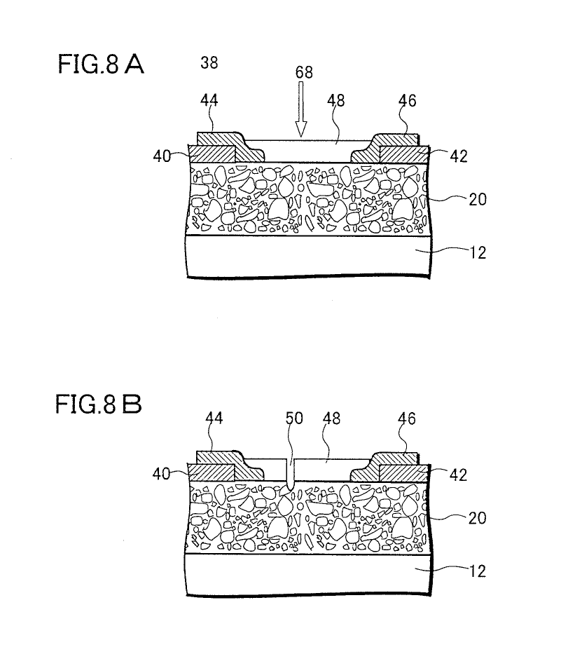

The adjustment of the resistance value of the resistor portion 38 by providing the cutout portion 50 by the laser processing will be described with reference to FIGS. 8A and 8B.

First, as shown in FIG. 8A, the resistor portion 38 includes the pads 40, 42 located on the upper surface of the insulating layer 20, the conductive pastes 44, 46 applied to the pads 40, 42, and the resistor body 48 applied to the upper surface of the insulating layer 20 at the portion surrounded by the conductive pastes 44, 46.

Here, the resistance value of the resistor portion 38 is determined by the cross-sectional area of the resistor body 48. However, the resistance value of the resistor body 48 in the originally applied state is different from a designed value. For this reason, it is necessary to perform an adjustment process to cut out part of the resistor body 48 while measuring the resistance value of the resistor portion 38 in order to adjust the resistance value of the resistor portion 38 to a predetermined value.

In this embodiment, the cross-sectional area and the resistance value of the resistor body 48 are adjusted to predetermined values by radiating the laser 68 from above onto the resistor body 48, thereby proving the cutout portion 50.

Here, as shown in FIG. 8B, the cutout portion 50 is provided by removing the laser-processed portion of the resistor body 48 in a groove shape. In other words, the laser processing is conducted to such an extent as to completely remove the resistor body 48 at the portion irradiated with the laser and to slightly remove the upper most layer of the insulating layer 20 located therebelow. Accordingly, when the insulating layer 20 is made of the transparent material, the laser beam that penetrates the resistor body 48 may pass through the insulating layer 20 and reach the substrate 12. Hence there is a risk of burning the upper surface of the substrate 12. However, the resin material included in the insulating layer 20 is colored according to this embodiment. Therefore, the laser beam radiated onto the insulating layer 20 is blocked at an upper part thereof and does not reach the substrate 12.

As described above, the laser processing of the present invention is employed as the method of manufacturing the circuit board.

Meanwhile, when a circuit device is manufactured by using the circuit board manufactured by the above-described processes, the circuit elements are firstly connected to the conductive pattern 16 as shown in FIG. 7A. Here, the circuit elements include the semiconductor element 24 to be connected by using the metal thin wires 32 as shown in FIG. 1B, and the chip element 28 to be connected by using solder. Further, as shown in FIG. 2A, the conductive pattern 16 and the substrate 12 exposed to the opening 36 at the connecting portion 34 are connected together by using the metal thin wire 32. Meanwhile, in the case of manufacturing an LED illuminating device, multiple LED chips are mounted on the upper surface of the substrate, and the LED chips are electrically connected to one another via the conductive pattern and the metal thin wires.

In addition, the circuit board provided with the circuit elements is sealed with a casing material or resin sealing. In the case of performing resin sealing, the circuit board is put into a cavity of a molding die and then the sealing resin is injected into the cavity.

The hybrid integrated circuit device 10 shown in FIG. 1A is manufactured by the above-described processes, for example.

According to the present invention, it is possible to perform laser processing easily on an insulating layer configured to cover an upper surface of a substrate. Specifically, even when transparent silica is used as a filler included in the insulating layer, a colorant is added to a resin material so that the entire insulating layer is colored to block a laser. Therefore, when the laser is radiated onto the insulating layer having the above-described configuration, the radiated laser is absorbed by the resin material in the insulating layer whereby the insulating layer is properly removed. Moreover, the laser is prevented from passing through the insulating layer and reaching the upper surface of the substrate. Hence it is possible to prevent the upper surface of the substrate from being burned as observed in the related art.

What is claimed is:

1. A circuit board comprising:
a substrate;
an insulating layer made of a resin material including a filler, the insulating layer covering an upper surface of the substrate; and
a conductive pattern formed on an upper surface of the insulating layer, wherein
silica is used as the filler included in the resin material, and
a colorant is added to the resin material.

2. The circuit board according to claim 1, wherein
at least part of the insulating layer is laser-processed.

3. The circuit board according to claim 1, further comprising:
an opening formed by partially removing the insulating layer by laser processing, wherein
the upper surface of the substrate is exposed to the opening.

4. The circuit board according to claim 3, further comprising:
connecting means for connecting the conductive pattern and the surface of the substrate exposed to the opening together.

5. The circuit board according to claim 1, wherein
a printed resistor is formed on the upper surface of the insulating layer, and
the printed resistor is partially cut and removed by laser processing.

6. The circuit board according to claim 1, wherein
the insulating layer at a peripheral portion of the substrate is cut out by laser processing.

7. A circuit device comprising:
the circuit board according to claim 1; and
a circuit element electrically connected to the conductive pattern.

8. A method of manufacturing a circuit board comprising the steps of:
preparing a substrate by covering an upper surface of the substrate with an insulating layer and forming a conductive pattern of a predetermined shape on a surface of the insulating layer; and
removing at least part of the insulating layer by laser processing, wherein
the insulating layer includes a resin material to which a colorant is added, and a filler made of silica, and
in the removing step, the colored resin material absorbs a laser, and thereby the resin material and the filler included in the insulating layer are removed.

9. The method of manufacturing a circuit board according to claim 8, wherein
in the removing step by laser processing, the upper surface of the substrate is exposed to an opening which is provided by removing the insulating layer by radiating the laser.

10. The method of manufacturing a circuit board according to claim 8, wherein
the removing step by laser processing is a step of performing laser processing to partially cut and remove a printed resistor provided on the upper surface of the insulating layer, and to partially remove the upper surface of the insulating layer covered with the printed resistor.

11. The method of manufacturing a circuit board according to claim 8, wherein
the removing step by laser processing is a step of separating the substrate and the insulating layer together into individual pieces.

12. A method of manufacturing a circuit device comprising the step of:
electrically connecting a circuit element to the conductive pattern of the circuit board manufactured by the method of manufacturing a circuit board according to claim 8.

13. A conductive foil provided with an insulating layer serving as a material of a conductive pattern to be electrically connected to a plurality of circuit elements on an upper surface of a substrate, comprising:
a conductive foil made of a conductive material; and
an insulating layer made of a resin material including a filler and attached to a principal surface of the conductive foil, wherein
silica is used as the filler included in the insulating layer, and
a colorant is added to the resin material.
